(19) United States
(12) Patent Application Publication
(10) Pub. No.: US 2019/0140774 A1
(43) Pub. Date: May 9, 2019

(54) METHOD FOR TRANSMITTING AND RECEIVING ACK/NACK IN NETWORK REQUIRING HIGHLY RELIABLE TRANSMISSION, AND COMMUNICATION DEVICE THEREFOR

(71) Applicant: LG ELECTRONICS INC., Seoul (KR)

(72) Inventors: Kwangseok NOH, Seoul (KR); Dongkyu KIM, Seoul (KR); Hyunsoo KO, Seoul (KR); Sangrim LEE, Seoul (KR); Hojae LEE, Seoul (KR)

(73) Assignee: LG ELECTRONICS INC., Seoul (KR)

(21) Appl. No.: 16/096,274

(22) PCT Filed: Apr. 26, 2016
(86) PCT No.: PCT/KR2016/004337

§ 371 Date: Oct. 24, 2018

(51) Int. Cl. H04L 1/00; H04L 5/00; H03M 13/09

(52) U.S. Cl. CPC H04L 1/0061; H03M 13/09; H04L 5/0044; H04L 5/0055

(57) ABSTRACT

According to the present invention, a method by which a communication device receives ACK/NACK can comprise the steps of: checking transport block (TB) cyclic redundancy check (CRC) after performing channel decoding on received data; and determining whether the terminal has received an ACK signal or has received a NACK signal, according to the TB CRC checking result.

### TECHNICAL FIELD

The present invention relates to wireless communication, and more particularly, to a method of transmitting and receiving ACK/NACK on a highly-reliable transmission required network and communication device therefor.

### BACKGROUND ART

In LTE system, an Acknowledgement/Not-acknowledgement (ACK/NACK) signal for feeding back success or failure in transmission is transmitted on Physical HARQ Indicator CHannel (PHICH) in Downlink (DL) or Physical Uplink Control Channel (PUCCH) or Physical Uplink Shared Channel (PUSCH) in Uplink (UL).

Particularly, PHICH is used for transmission of Hybrid Automatic Repeat Request (HARQ) acknowledgements for UL-SCH transmission. One PHICH per received transport block is transmitted per Transmission Time Interval (TTI). HARQ ACK that is 1-bit information is repeated three times, BPSK-modulated, and then spread into a length-4 orthogonal sequence.

Therefore, total 12-bit resource allocation is required for 1-bit transmission. PHICH carries an ACK/NACK signal for UL HARQ. Namely, ACK/NACK Signal for UL data on PUSCH transmitted by a User Equipment (UE) is transmitted on PHICH by a Base Station (BS)

### DISCLOSURE OF THE INVENTION

### Technical Tasks

One technical task achieved by the present invention is to provide a method of receiving ACK/NACK on a highly-reliable transmission required network.

Another technical task achieved by the present invention is to provide a method of transmitting ACK/NACK on a highly-reliable transmission required network.

Further technical task achieved by the present invention is to provide a communication device for receiving ACK/NACK on a highly-reliable transmission required network.

Another further technical task achieved by the present invention is to provide a communication device for transmitting ACK/NACK on a highly-reliable transmission required network.

Technical tasks obtainable from the present invention are non-limited by the above-mentioned technical task. And, other unmentioned technical tasks can be clearly understood from the following description by those having ordinary skill in the technical field to which the present invention pertains.

### Technical Solutions

In one technical aspect of the present invention, provided herein is a method for receiving ACK/NACK by a communication apparatus, the method including checking a Transport Block (TB) Cyclic Redundancy Check (CRC) after performing channel decoding for received data and determining whether the user equipment receives an ACK signal or a NACK signal according to a result of the TB CRC test.

If the checking of the TB CRC test is success, it is determined that a reception of the data may be successful and ACK for a previous data transmission of the communication apparatus may be received.

If the checking of the TB CRC is failure, the TB CRC may be re-checked by applying a pre-defined NACK mask. If the checking of the TB CRC is success as a result of the re-check, it is determined that a reception of the data may be as successful and NACK for previous data transmission of the communication apparatus may be received. The pre-defined NACK mask may be defined in a manner that an exclusive OR (XOR) operation result with an ACK mask becomes all ‘1’.

The TB CRC may be checked by applying a pre-defined ACK mask to the TB CRC.

If the checking of the TB CRC is failure, the TB CRC may be re-checked by applying a pre-defined NACK mask. If the checking of the TB CRC is failure again, a reception of the data may be determined as failure and a signal for requesting retransmission of the data may be transmitted to a node having transmitted the data.

In another technical aspect of the present invention, provided herein is a method for transmitting ACK/NACK by a communication device, the method including applying a pre-defined ACK or NACK mask to a Transport Block (TB) generated for data transmission, encoding the TB to which the ACK or NACK mask is applied and transmitting the encoded TB. The ACK mask and the NACK mask may be defined in a manner that a result from an exclusive OR (XOR) operation between the ACK mask and the NACK mask becomes all ‘1’.

In another technical aspect of the present invention, provided herein is a communication apparatus for receiving ACK/NACK by a communication apparatus, the communication apparatus comprises a processor configured to check a Transport Block (TB) Cyclic Redundancy Check (CRC) after performing channel decoding for received data and determine whether the user equipment receives an ACK signal or a NACK signal according to a result of the checking of the TB CRC.

If the checking of the TB CRC is success, the processor may determine that a reception of the data is successful and ACK for previous data transmission of the communication apparatus is received.

If the checking of the TB CRC is failure, the processor may re-check the TB CRC by applying a pre-defined NACK mask. If the checking of the TB CRC is success as a result of the re-check, the processor may determine that a reception of the data is successful and NACK for previous data transmission of the communication device is received.

The processor may check the TB CRC by applying a pre-defined ACK mask to the TB CRC.

The communication apparatus may further include a transmitter. If the checking of the TB CRC is failure, the processor may re-check the TB CRC by applying a pre-defined NACK mask. If the checking of the TB CRC is failure again, the processor may determine that a reception of the data is failure, and the processor controls the transmitter to transmit a signal for requesting retransmission of the data to a node having transmitted the data.

The pre-defined NACK mask may be defined in a manner that an exclusive OR (XOR) operation result with an ACK mask becomes all ‘1’.

In another technical aspect of the present invention, provided herein is a communication apparatus for transmitting ACK/NACK, the communication apparatus comprises a processor for applying a pre-defined ACK or NACK mask to a Transport Block (TB) generated for data transmission and a transmitter for transmitting the TB after encoding the TB. The ACK mask and the NACK mask may be defined in a manner that a result from an exclusive OR (XOR) operation between the ACK mask and the NACK mask becomes all ‘1’.

### Advantageous Effects

According to one embodiment of the present invention, by considerably reducing resource allocation overhead for ACK/NACK transmission on a highly-reliable transmission required network, communication performance can be improved.

Effects obtainable from the present invention are non-limited by the above mentioned effect. And, other unmentioned effects can be clearly understood from the following description by those having ordinary skill in the technical field to which the present invention pertains.

### DESCRIPTION OF DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a block diagram showing configurations of a base station 105 and a user equipment 110 in a wireless communication system 100.

FIG. 2 is a diagram showing a Transport Block (TB) process in an LTE system.

FIG. 3 is a diagram of an example of an ACL/NACK mask method proposed by the present invention.

FIG. 4 is a diagram showing a sequence for applying an ACK/NACK mask proposed by the present invention.

### BEST MODE FOR INVENTION

Reference will now be made in detail to the preferred embodiments of the present invention, examples of which are illustrated in the accompanying drawings. In the following detailed description of the invention includes details to help the full understanding of the present invention. Yet, it is apparent to those skilled in the art that the present invention can be implemented without these details. For instance, although the following descriptions are made in detail on the assumption that a mobile communication system includes 3GPP LTE system, the following descriptions are applicable to other random mobile communication systems in a manner of excluding unique features of the 3GPP LTE.

Occasionally, to prevent the present invention from getting vaguer, structures and/or devices known to the public are skipped or can be represented as block diagrams centering on the core functions of the structures and/or devices. Wherever possible, the same reference numbers will be used throughout the drawings to refer to the same or like parts.

Besides, in the following description, assume that a terminal is a common name of such a mobile or fixed user stage device as a user equipment (UE), a mobile station (MS), an advanced mobile station (AMS) and the like. And, assume that a base station (BS) is a common name of such a random node of a network stage communicating with a terminal as a Node B (NB), an eNode B (eNB), an access point (AP) and the like. Although the present specification is described based on IEEE 802.16m system, contents of the present invention may be applicable to various kinds of other communication systems.

In a mobile communication system, a user equipment is able to receive information in downlink and is able to transmit information in uplink as well. Information transmitted or received by the user equipment node may include various kinds of data and control information. In accordance with types and usages of the information transmitted or received by the user equipment, various physical channels may exist.

The following descriptions are usable for various wireless access systems including CDMA (code division multiple access), FDMA (frequency division multiple access), TDMA (time division multiple access), OFDMA (orthogonal frequency division multiple access), SC-FDMA (single carrier frequency division multiple access) and the like. CDMA can be implemented by such a radio technology as UTRA (universal terrestrial radio access), CDMA 2000 and the like. TDMA can be implemented with such a radio technology as GSM/GPRS/EDGE (Global System for Mobile communications)/General Packet Radio Service/Enhanced Data Rates for GSM Evolution). OFDMA can be implemented with such a radio technology as IEEE 802.11 (Wi-Fi), IEEE 802.16 (WiMAX), IEEE 802.20, E-UTRA (Evolved UTRA), etc. UTRA is a part of UMTS (Universal Mobile Telecommunications System). 3GPP (3rd Generation Partnership Project) LTE (long term evolution) is a part of E-UMTS (Evolved UMTS) that uses E-UTRA. The 3GPP LTE employs OFDMA in DL and SC-FDMA in UL. And, LTE-A (LTE-Advanced) is an evolved version of 3GPP LTE.

Moreover, in the following description, specific terminologies are provided to help the understanding of the present invention. And, the use of the specific terminology can be modified into another form within the scope of the technical idea of the present invention.

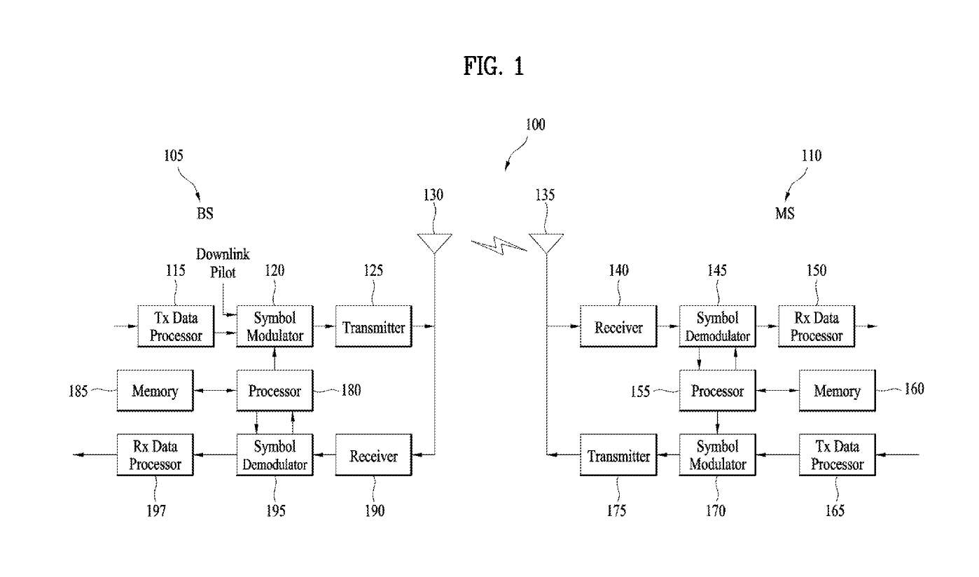

FIG. 1 is a block diagram for configurations of a base station 105 and a user equipment 110 in a wireless communication system 100.

Although one base station 105 and one user equipment 110 (D2D user equipment included) are shown in the drawing to schematically represent a wireless communication system 100, the wireless communication system 100 may include at least one base station and/or at least one user equipment.

Referring to FIG. 1, a base station 105 may include a transmitted (Tx) data processor 115, a symbol modulator 120, a transmitter 125, a transceiving antenna 130, a processor 180, a memory 185, a receiver 190, a symbol demodulator 195 and a received data processor 197. And, a user equipment 110 may include a transmitted (Tx) data processor 165, a symbol modulator 170, a transmitter 175, a transceiving antenna 135, a processor 155, a memory 160, a receiver 140, a symbol demodulator 155 and a received data processor 150. Although the base station/user equipment 105/110 includes one antenna 130/135 in the drawing, each of the base station 105 and the user equipment 110 includes a plurality of antennas. Therefore, each of the base station 105 and the user equipment 110 of the present invention supports an MIMO (multiple input multiple output) system. And, the base station 105 according to the present invention may support both SU-MIMO (single user-MIMO) and MU-MIMO (multi user-MIMO) systems.

In downlink, the transmission data processor 115 receives traffic data, codes the received traffic data by formatting the received traffic data, interleaves the coded traffic data, modulates (or symbol maps) the interleaved data, and then provides modulated symbols (data symbols). The symbol modulator 120 provides a stream of symbols by receiving and processing the data symbols and pilot symbols.

The symbol modulator 120 multiplexes the data and pilot symbols together and then transmits the multiplexed symbols to the transmitter 125. In doing so, each of the transmitted symbols may include the data symbol, the pilot symbol or a signal value of zero. In each symbol duration, pilot symbols may be contiguously transmitted. In doing so, the pilot symbols may include symbols of frequency division multiplexing (FDM), orthogonal frequency division multiplexing (OFDM), or code division multiplexing (CDM).

The transmitter 125 receives the stream of the symbols, converts the received stream to at least one or more analog signals, additionally adjusts the analog signals (e.g., amplification, filtering, frequency upconverting), and then generates a downlink signal suitable for a transmission on a radio channel Subsequently, the downlink signal is transmitted to the user equipment via the antenna 130.

In the configuration of the user equipment 110, the receiving antenna 135 receives the downlink signal from the base station and then provides the received signal to the receiver 140. The receiver 140 adjusts the received signal (e.g., filtering, amplification and frequency downconverting), digitizes the adjusted signal, and then obtains samples. The symbol demodulator 145 demodulates the received pilot symbols and then provides them to the processor 155 for channel estimation.

The symbol demodulator 145 receives a frequency response estimated value for downlink from the processor 155, performs data demodulation on the received data symbols, obtains data symbol estimated values (i.e., estimated values of the transmitted data symbols), and then provides the data symbols estimated values to the received (Rx) data processor 150. The received data processor 150 reconstructs the transmitted traffic data by performing demodulation (i.e., symbol demapping, deinterleaving and decoding) on the data symbol estimated values.

The processing by the symbol demodulator 145 and the processing by the received data processor 150 are complementary to the processing by the symbol modulator 120 and the processing by the transmission data processor 115 in the base station 105, respectively.

In the user equipment 110 in uplink, the transmission data processor 165 processes the traffic data and then provides data symbols. The symbol modulator 170 receives the data symbols, multiplexes the received data symbols, performs modulation on the multiplexed symbols, and then provides a stream of the symbols to the transmitter 175. The transmitter 175 receives the stream of the symbols, processes the received stream, and generates an uplink signal. This uplink signal is then transmitted to the base station 105 via the antenna 135.

In the base station 105, the uplink signal is received from the user equipment 110 via the antenna 130. The receiver 190 processes the received uplink signal and then obtains samples. Subsequently, the symbol demodulator 195 processes the samples and then provides pilot symbols received in uplink and a data symbol estimated value. The received data processor 197 processes the data symbol estimated value and then reconstructs the traffic data transmitted from the user equipment 110.

The processor 155/180 of the user equipment/base station 110/105 directs operations (e.g., control, adjustment, management, etc.) of the user equipment/base station 110/105. The processor 155/180 may be connected to the memory unit 160/185 configured to store program codes and data. The memory 160/185 is connected to the processor 155/180 to store operating systems, applications and general files.

The processor 155/180 may be called one of a controller, a microcontroller, a microprocessor, a microcomputer and the like. And, the processor 155/180 may be implemented using hardware, firmware, software and/or any combinations thereof. In the implementation by hardware, the processor 155/180 may be provided with such a device configured to implement the present invention as ASICs (application specific integrated circuits), DSPs (digital signal processors), DSPDs (digital signal processing devices), PLDs (programmable logic devices), FPGAs (field programmable gate arrays), and the like.

Meanwhile, in case of implementing the embodiments of the present invention using firmware or software, the firmware or software may be configured to include modules, procedures, and/or functions for performing the above-explained functions or operations of the present invention. And, the firmware or software configured to implement the present invention is loaded in the processor 155/180 or saved in the memory 160/185 to be driven by the processor 155/180.

Layers of a radio protocol between a user equipment/base station and a wireless communication system (network) may be classified into 1st layer L1, 2nd layer L2 and 3rd layer L3 based on 3 lower layers of OSI (open system interconnection) model well known to communication systems. A physical layer belongs to the 1st layer and provides an information transfer service via a physical channel. RRC (radio resource control) layer belongs to the 3rd layer and provides control radio resourced between UE and network. A user equipment and a base station may be able to exchange RRC messages with each other through a wireless communication network and RRC layers.

In the present specification, although the processor 155/180 of the user equipment/base station performs an operation of processing signals and data except a function for the user equipment/base station 110/105 to receive or transmit a signal, for clarity, the processors 155 and 180 will not be mentioned in the following description specifically. In the following description, the processor 155/180 can be regarded as performing a series of operations such as a data processing and the like except a function of receiving or transmitting a signal without being specially mentioned.

The present invention relates to ACK/NACK signal transmission for data received in UL/DL, and proposes a scheme for ACK/NACK transmission without independent resource allocation for ACK/NACK.

In UL, PUCCH format 1 is used for transmission of Scheduling Request (SR), PUCCH format 1a/1b is used for transmission of an ACK/NACK Signal for HARQ, PUCCH format 2 is sued for CQI transmission, and PUCCH format 2a/2b is used for simultaneous transmission of CQI and ACK/NACK. If a attempts to transmit data on PUSCH by receiving a valid scheduling grant in a subframe (e.g., configuration with two slots in length of 10 ms), control information may be transmitted on PUSCH by being time-multiplexed together with data without using PUCCH.

In cased of Frequency Division Duplex (FDD) mode, ACK/NACK Signal is transmitted in an (i+4)^{th} Tx subframe (subframe i+4) for an i^{th} Tx subframe (subframe i). Based on this, an (i+8)^{th} Tx subframe (subframe i+8) is used for data retransmission. This considers a time for processing a transport block and a time required for generating ACK/NACK, in which a channel code processing consumes the longest time. In case of Time Division Duplex (TDD) mode, TDD UL/ uses a different transmission time per configuration in consideration of such a consumed time and a UL subframe assignment and also uses bundling and multiplexing schemes.

As one of fields gradually becoming important for the realization of the 5G communication technology, there is reliable communication. The reliable communication means a new communication service realized through error free transmission or service availability for the realization of Mission Critical Service (MCS). METIS mentions the necessity for reliable communication as a way of M2M communication having real-time requirements for traffic safety, traffic efficiency, e-health, efficient industrial communication and the like. It is necessary to provide reliable communication for such applications sensitive to delay as traffic safety or mission critical MTCs for special purposes. The reliable communication is necessary for the purpose of medical/emergency response, remote control, sensing and the like.

3^{rd} Generation Partnership Project (3GPP) has discussed about detailed service scenes for MCSs. And, the MCS are overall estimated to require numerous enhancements in aspects of UMTS/LTE, LTE-A/Wi-Fi versus end-to-end latency, ubiquity, security, availability/reliability and the like. Namely, the commercial wireless technologies (3GPP LTE, LTE-A included) proposed so far fails to secure performance enough to provide the above-mentioned various MCSs in aspects of real-time requirements and reliability requirements.

In reliable communication, a transmission error rate is very low in comparison with LTE. For example, in case of targeting a success rate of 99.999%, it means that a single transmission error occurs from about 10,000 transmissions. A mainly targeted success rate in LTE system is 90%, which means that a single transmission error occurs from about 10 transmissions. Hence, since there could be variation of an error rate due to appropriate Modulation Coding and Scheme (MCS) level selection in LTE system, ACK/NACK is transmitted in every TTI.

Yet, since a transmission error rate is very low in reliable communication, ACK will be transmitted mostly. Hence, if ACK is transmitted in every TTI, it considerably lowers transmission efficiency. Therefore, it may be an appropriate method that NACK generated once at 1/target Packet Error Rate (PER) is transmitted only. If it is associated with a current LTE technology to send an occasionally generated NACK, two cases can be considered as follows. First of all, a resource can be allocated to an independent region like the LTE system. Secondly, after NACK is transmitted by being included in transmission data, it is able to use signaling that indicates that NACK is included. Yet, the two methods have the following problems. Resource allocation for NACK to be assigned occasionally becomes a waste. Since NACK is 1 bit, it has the same overhead as the current LTE system. Moreover, since at least 1 bit should be added for new signaling and a stable operation should be secured, it has the same overhead as the current LTE system.

In case of PHICH transmission, a base station controls PHICH transmit power to prevent ACK-to-NACK or NACK-to-ACK error. PHICH can be mapped to Resource Element (RE) used by the PHICH. If a dynamically changing PHICH power configuration is considered, a considerable transmit power deviation may be generated between Res.

According to the present invention, as an RE exclusively used by PHICH is not mapped, such a problem can be solved. And, it may bring an effect that a 12-bit resource use can be reduced. Thus, the present invention intends to propose a scheme of transmitting NACK without using new resource allocation/signaling. Particularly, it is intended to propose a scheme of determining ACK/NACK by checking CRC connected to Transport Block (TB) or Code Block (CB).

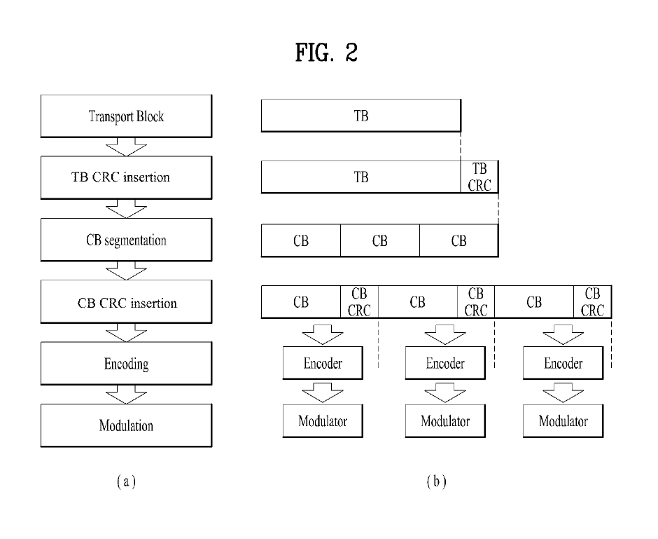

FIG. 2 is a diagram showing a Transport Block (TB) process in an LTE system.

FIG. 2 (a) is a diagram showing channel code coding processes, and FIG. 2 (b) is a diagram showing a TB configuration for a coding process.

Referring to FIG. 2(a), a channel code coding process includes a step 1) of configuring a TB, a step 2) of inserting Cyclic Redundancy Check (CRC) in the TB, a step 3) of performing a CB segmentation, a step 4) of inserting CRC in a CB, a step 5) of performing encoding, and a step 6) of performing modulation.

Referring to FIG. 2(b), an input symbol size may be different from a Transport Block (TB) size from Medium Access Control (MAC). If TB is bigger than a maximum input symbol size of a turbo code, it is segmented into several Code Blocks (CBs). In this case, a CB size becomes 6144-CRC bits. An input symbol of the turbo code defines a data use including CB and CRC or TB (<6144) and CRC.

In a decoding process of a channel code, as a process opposite to FIG. 2, a decoder corresponding to each encoder is used. After decoding has been performed in each CB unit, a presence or non-presence of a TB CRC pass by finally configuring a TB.

A turbo code in LTE system is described for example, and other codes may be usable.

The present invention discloses an embodiment of a case that a TB is smaller than 6,144 (TB size=CB size). For clarity of the description, ACK/NACK is described on the assumption that ACK/NACK for UL transmission is transmitted.

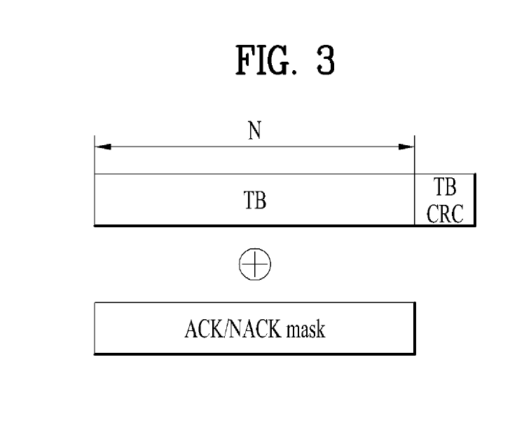

FIG. 3 is a diagram of an example of an ACL/NACK mask method proposed by the present invention.

Referring to FIG. 3, as described above, channel code encoding is performed in TB unit. Hence, for ACK/NACK transmission, data (TB) to be sent can be transmitted by applying a mask for ACK/NACK to the data.

Particularly, when TB size =CB size, if a data length is N bits, an ACK mask can have N bits correspond to all zero sequence and a NACK mask can have N bits correspond to all one sequence. In this case, if a condition that a result of an exclusive OR operation between masks becomes all one sequence is satisfied only, the ACK/NACK mask can be configured in various forms. The condition that the exclusive OR operation result becomes all one sequence becomes a necessary condition for classifying ACK/NACK using CRC.

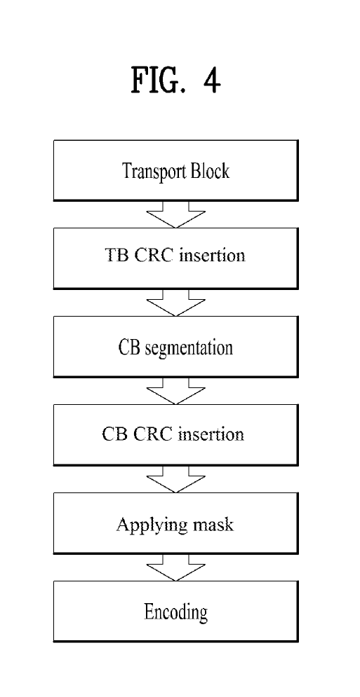

FIG. 4 is a diagram showing a sequence for applying an ACK/NACK mask proposed by the present invention.

Referring to FIG. 4, if a TB size is greater than a CB size, an ACK/NACK mask applying method shown in FIG. 4 can be considered. A TB is generated and a TB CRC is inserted in the TB. CB segmentation for dividing the TB into a plurality of CB s is performed and a CRC is inserted in each of the CBs. Thereafter, an ACK/NACK mask is applied to the TB and then encoding is performed. If an ACK mask is all zero sequence, I is able to skip the ACK mask application.

Since the ACK/NACK mas is spread in the whole data region, transmit power deviation on PHICH does not occur. Moreover, as highly-reliable transmission is performed (i.e., almost no error occurs from data, a scheme of repeatedly spreading ACK/NACK for highly-reliable ACK/NACK transmission is not necessary.

Since data transmission is assumed as UL transmission and ACK/NACK is assumed as transmitting ACK/NACK for UL transmission in DL, an ACK/NACK detection scheme in a UE is described as follows.

First of all, a UE performs channel decoding on TB (e.g., TB size=CB size) and a CRC test is then performed by applying an ACK mask. If the ACK mask is all zero sequence, the ACK mask application can be skipped. If the UE succeeds in the CRC test, the UE can be aware of ACK reception as well as DL data transmission success. On the contrary, if UE fails in the CRC test, the UE performs the CRC test again by applying a NACK mask.

If the CRC test performed by applying the NACK mask is determined as success, the UE can determine that the DL data transmission was successful and also determine that NACK has been received. Yet, if the CRC test performed by applying the NACK mask is failure, the UE can be aware that the DL data transmission is failure and ACK/NACK distinction becomes impossible due to error for data. therefore, only if the CRC test performed by applying the NACK mask is failure, the UE can make a request for retransmission to the base station. The base station can retransmit ACK/NACK to the UE as well as data.

Thus, it is not necessary for a base station to allocate a resource for PHICH transmission, which carries ACK/NACK signal for UL HARQ, to a UE. Only if the UE fails in a CRC test performed by applying a NACK mask, the base station transmits ACK/NACK information by applying ACK/NACK mask again in case of data retransmission in response to a UE's request, whereby resource overhead attributed to ACK/NACK resource transmission can be reduced considerably.

The above-mentioned embodiments correspond to combinations of elements and features of the present invention in prescribed forms. And, it is able to consider that the respective elements or features are selective unless they are explicitly mentioned. Each of the elements or features can be implemented in a form failing to be combined with other elements or features. Moreover, it is able to implement an embodiment of the present invention by combining elements and/or features together in part. A sequence of operations explained for each embodiment of the present invention can be modified. Some configurations or features of one embodiment can be included in another embodiment or can be substituted for corresponding configurations or features of another embodiment. And, it is apparently understandable that an embodiment is configured by combining claims failing to have relation of explicit citation in the appended claims together or can be included as new claims by amendment after filing an application.

While the present invention has been described and illustrated herein with reference to the preferred embodiments thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

### INDUSTRIAL APPLICABILITY

A method of transmitting and receiving ACK/NACK on a highly-reliable transmission required network and communication device therefor are industrially applicable to the next generation communication systems such as 5G communication system and the like.

What is claimed is:

1. A method for receiving ACK/NACK by a communication apparatus, the method comprising:
checking a transport block (TB) Cyclic Redundancy Check (CRC) after performing channel decoding for received data; and
determining whether the user equipment receives an ACK signal or a NACK signal based on a result of the checking of the TB CRC.

2. The method of claim 1, wherein if the checking of the TB CRC is success, it is determined that a reception of the data is successful and ACK for a previous data transmission of the communication apparatus is received.

3. The method of claim 1, wherein if the checking of the TB CRC is failure, re-checking the TB CRC by applying a pre-defined NACK mask, and
wherein if the checking of the TB CRC is success as a result of the re-checking, it is determined that a reception of the data is successful and NACK for a previous data transmission of the communication apparatus is received.

4. The method of claim 1, wherein the TB CRC is checked by applying a pre-defined ACK mask to the TB CRC.

5. The method of claim 1, wherein if the checking of the TB CRC is failure, the TB CRC is re-checked by applying a pre-defined NACK mask, and
wherein if the checking of the TB CRC is failure again, the reception of the data is determined as failure and a signal for requesting retransmission of the data is transmitted to a node having transmitted the data.

6. The method of claim 3, wherein the pre-defined NACK mask is defined in a manner that an exclusive OR (XOR) operation result with an ACK mask becomes all ‘1’.

7. A method for transmitting ACK/NACK by a communication apparatus, the method comprising:
applying a pre-defined ACK or NACK mask to a transport block (TB) generated for data transmission; and
encoding the TB to which the ACK or NACK mask is applied and transmitting the encoded TB.

8. The method of claim 7, wherein the ACK mask and the NACK mask are defined in a manner that a result from an exclusive OR (XOR) operation between the ACK mask and the NACK mask becomes all ‘1’.

9. A communication apparatus for receiving ACK/NACK by a communication device, the communication apparatus comprising:
a processor configured to:
check a transport block (TB) Cyclic Redundancy Check (CRC) after performing channel decoding for received data; and
determine whether the user equipment receives an ACK signal or a NACK signal according to a result of the checking of the TB CRC.

10. The communication apparatus of claim 9, wherein if the checking of the TB CRC is success, the processor determines that a reception of the data is successful and ACK for previous data transmission of the communication device is received.

11. The communication apparatus of claim 9, wherein if the checking of the TB CRC is failure, the processor re-checks the TB CRC by applying a pre-defined NACK mask, and
wherein if the checking of the TB CRC is success as a result of the re-check, the processor determines that a reception of the data is successful and NACK for previous data transmission of the communication apparatus is received.

12. The communication apparatus of claim 9, wherein the processor checks the TB CRC by applying a pre-defined ACK mask to the TB CRC.

13. The communication apparatus of claim 9, further comprising:
a transmitter, wherein if the checking of the TB CRC test is failure, the processor re-checks the TB CRC by applying a pre-defined NACK mask, and
wherein if the checking of the TB CRC test is failure again, the processor determines a reception of the data as failure and controls the transmitter to transmit a signal for requesting retransmission of the data to a node having transmitted the data.

14. The communication apparatus of claim 9, wherein the pre-defined NACK mask is defined in a manner that an exclusive OR (XOR) operation result with an ACK mask becomes all ‘1’.

15. A communication apparatus for transmitting ACK/NACK, the communication apparatus comprising:
a processor for applying a pre-defined ACK or NACK mask to a Transport Block (TB) generated for data transmission; and
a transmitter for transmitting the TB after encoding the TB.

16. The communication apparatus of claim 15, wherein the ACK mask and the NACK mask are defined in a manner that a result from an exclusive OR (XOR) operation between the ACK mask and the NACK mask becomes all ‘1’.
